(19) United States
(12) Patent Application Publication
(10) Pub. No.: US 2014/0174341 A1
(43) Pub. Date: Jun. 26, 2014

(54) CRUCIBLE FOR GROWING CRYSTALS

(71) Applicants: Bernd Kleinpass, Pfronten (DE); Hermann Walser, Breitenwang (AT)

(72) Inventors: Bernd Kleinpass, Pfronten (DE); Hermann Walser, Breitenwang (AT)

(73) Assignee: PLANSEE SE, REUTTE (AT)

(21) Appl. No.: 14/237,267

(22) PCT Filed: Aug. 3, 2012
(86) PCT No.: PCT/AT2012/000206

§ 371 Date: Feb. 21, 2014

(30) Foreign Application Priority Data
Aug. 5, 2011 (AT) GM 445/2011

(51) Int. Cl. C30B 11/00; C30B 35/00

(52) U.S. Cl. CPC C30B 11/002; C30B 35/002
USPC 117/81; 117/223; 117/208

(57) ABSTRACT

A crucible for growing crystals, in particular a sapphire single crystal, includes a base crucible made of W, Mo, Re or an alloy of these materials and an inner lining made of W, Mo, Re or an alloy of these materials. The base crucible has a substantially pot-like form. The inner lining has at least a pot-like first portion, which covers a bottom region of the base crucible, and a jacket-like second portion, which at least partially covers a wall region of the base crucible. The first portion and the second portion are formed by separate components. A process for growing sapphire single crystals using a crucible is also provided.

The present invention relates to a crucible for growing crystals, in particular a sapphire single crystal, to a process for growing sapphire single crystals using such a crucible and to the use of such a crucible for growing sapphire single crystals.

The growth of sapphire single crystals has been undertaken very intensively for a number of years, since single-crystal sapphire substrates are used in particular for the epitaxial deposition of gallium nitride (GaN) used widely for producing, inter alia, LEDs (light emitting diodes) and certain semiconductor lasers.

Various processes for growing sapphire single crystals are known. Processes which have become established are in particular those in which the single crystal growth is effected in such a manner that a seed crystal, on the basis of which the single crystal growth is effected, is slowly pulled partially or completely from the molten Al₂O₃, or in which the single crystal growth is effected from molten Al₂O₃ in such a manner that a seed crystal is placed in the bottom region of a crucible and countercooled in a controlled manner, in order to achieve slow deposition from the molten Al₂O₃. In these processes, use is commonly made in each case of crucibles consisting of high-melting metals, in particular of Mo, W, Ir or Mo—W alloys. The production of a sapphire single crystal which is free of impurities to the greatest possible extent depends greatly on a high degree of purity of the crucible materials used and on the resistance thereof to the molten mass and high temperatures.

On account of the required high purity of the crucible material and the need for high-melting crucible materials, the costs apportioned to the crucible represent an essential aspect in terms of cost for the growth of sapphire single crystals. Particularly in the growth of sapphire single crystals where the single crystal growth is effected on the basis of a seed crystal placed in the bottom region of a crucible, it is also not possible in the processes used to date to remove the sapphire single crystal which has formed from the crucible without destroying the crucible in the process. This results inter alia from the single crystal adhering to the crucible material and from deformation of the crucible during the process.

DE 10 2008 060 520 A1 describes a crucible and a process for processing a high-melting material in this crucible, wherein that part of the surface of the crucible which comes into contact with the molten mass of the high-melting material is covered with a foil consisting of a metal, the metal having a melting point of at least 1800° C.

It is an object of the present invention to provide a crucible for growing crystals and a process for growing sapphire single crystals using such a crucible, with which it is possible to reduce the costs apportioned to the crucible for the growth of sapphire single crystals.

The object is achieved by a crucible for growing crystals as claimed in claim 1. Advantageous developments are indicated in the dependent claims.

The crucible has a base crucible made of W, Mo, Re or an alloy of these materials and an inner lining made of W, Mo, Re or an alloy of these materials. The base crucible has a substantially pot-like form and the inner lining has at least a pot-like first portion, which covers a bottom region of the base crucible, and a jacket-like second portion, which at least partially covers a wall region of the base crucible. The first portion and the second portion are formed by separate components.

In the present context, “an alloy of these materials” is understood to mean a W—Mo alloy, a W—Re alloy, an Mo—Re alloy or a W—Mo—Re alloy. Since the base crucible is provided with the inner lining, repeated use of the base crucible for growing sapphire single crystals is made possible, where merely the inner lining needs to be replaced for the production of a further single crystal. The inner lining can in this case be formed with a considerably smaller wall thickness than the base crucible, as a result of which a significant saving of material is made. The provision of the inner lining avoids corrosion of the base crucible caused by the molten Al₂O₃ at least to the greatest possible extent, and therefore a considerably higher service life of the base crucible is achieved. Since the inner lining has the pot-like first portion and the jacket-like second portion, which are formed by separate components, particularly efficient and cost-effective production of the inner lining is made possible. The pot-like design of the first portion provides, in particular in the particularly critical bottom region, a configuration in which the inner lining is impermeable with respect to the molten Al₂O₃. On account of the configuration with the first portion and the second portion, the pot-like first portion can be produced particularly efficiently and inexpensively by forming from a foil. It can be produced, for example, by deep drawing or pressing with corresponding shapes. The jacket-like second portion can be produced particularly efficiently and inexpensively by unwinding from a foil. The first portion and the second portion are in this case preferably produced from the same material. Compared with the production of an inner lining from one component, more cost-effective production is achieved, in which the first portion in particular can be efficiently formed like a pot.

Furthermore, the solution described also makes it possible to provide a better surface quality of the inner lining coming into contact with the molten Al₂O₃ or the sapphire single crystal, since for example a rolled strip or thin metal sheet utilized for the inner lining will or can have a higher surface quality than a single-part crucible machined by pressing or turning. It is therefore possible to achieve a better visual quality of the sapphire single crystal, which is advantageous for visual quality assessment.

The first portion and the second portion can be fixedly connected to one another, for example. The two portions can in this case be fixedly connected to one another in particular in such a manner that the inner lining is impermeable with respect to the molten Al₂O₃, and the latter does not come into contact with the material of the base crucible. The fixed connection can be made in particular by an integral connection, e.g. by welding, by being sintered to one another, etc., or by forming of regions of the first portion and/or of the second portion and connection by engaging in one another or by a combination of these connection techniques. As an alternative to a fixed connection, the first portion and the second portion can also merely rest sealingly against one another, for example. By way of example, a second portion formed by a coiled foil can also be placed with its bottom end in the first portion, where it can be supported sealingly against the first portion owing to its residual stress, i.e. its rolling force, and if appropriate the pressure exerted by Al₂O₃ starting material or molten Al₂O₃.

The base crucible and the inner lining are preferably matched to one another in such a manner that the inner lining can be detached from the base crucible together with the sapphire single crystal after the single crystal growth. This can be achieved in particular by a suitable material selection for the base crucible and the inner lining, by suitably matching the dimensions of the base crucible and of the inner lining and by structuring the contact regions between the base crucible and the inner lining.

If the pot-like first portion is formed by forming from a foil, this makes it possible to achieve particularly cost-effective production which achieves an impermeable configuration of the inner lining in the bottom region of the crucible. The forming may have been effected in this case by deep drawing or by pressing into a corresponding shape, for example.

If the second portion is formed from a wound foil, this also makes it possible to achieve particularly efficient and cost-effective production of the second portion. By way of example, the second portion can be formed by a foil which is coiled to form a substantially hollow-cylindrical shape, the connection joint being formed in such a manner that it is impermeable with respect to the molten Al₂O₃.

According to one embodiment, the first portion and the second portion are integrally connected to one another. In this case, it is reliably ensured that the inner lining is impermeable with respect to the molten Al₂O₃ and the latter does not come into contact with the base crucible. The integral connection can be made, for example, by welding or sintering.

According to one configuration, the first portion and the second portion are connected to one another by way of regions of the first portion and of the second portion engaging into one another. By way of example, a region of the first portion and/or a region of the second portion may be bent, for example in the form of a fold, and the region of the first portion and the region of the second portion can be hooked to one another. If appropriate, this type of connection can be combined with an integral connection, e.g. by welding or sintering. In this case, a particularly reliable connection able to withstand loading is provided.

According to a preferred configuration, provision is made of a structure for facilitating the separability of the inner lining from the base crucible after formation of a sapphire single crystal. In terms of simplified production, at least the outer side of the inner lining in particular can be provided with surface structuring. The surface structuring can be introduced, for example by embossing, into the material of the inner lining and/or of the base crucible. It is preferable that the surface structuring can be formed in such a manner as to facilitate the separability of the inner lining and base crucible after the formation of a sapphire single crystal. By way of example, the surface structuring can be formed in such a manner that the inner lining touches the base crucible only in certain regions. Alternatively, it is also possible, for example, to configure the structure as a separate intermediate element arranged at least in certain regions between the base crucible and the inner lining.

The object is also achieved by a crucible for growing crystals as claimed in claim 7. Advantageous developments are indicated in the dependent claims.

The crucible has a base crucible made of W, Mo, Re or an alloy of these materials and an inner lining made of W, Mo, Re or an alloy of these materials. The base crucible has a substantially pot-like form and the inner lining has a smaller wall thickness than the base crucible. Provision is made of a structure for facilitating the separability of the inner lining from the base crucible after formation of a sapphire single crystal. The structure can be formed, for example, from the material of the inner lining or from the material of the base crucible, in particular in the form of structuring of the surface of the inner lining and/or of the base crucible. However, it is also possible, for example, to configure the structure as a separate element arranged at least in certain regions between the base crucible and the inner lining.

According to one configuration, the structure is formed by structuring the surface of at least an outer side of the inner lining and/or of at least an inner side of the base crucible. In this case, good removability of the sapphire single crystal which has formed from the base crucible is achieved with a structurally very simple design of the crucible, and therefore said base crucible can be reliably used repeatedly.

According to one configuration, the structure is formed by a separate intermediate element arranged between the inner lining and the base crucible. It is possible in this respect, for example, to provide the intermediate element universally between the inner lining and the base crucible, but also, for example, to provide the intermediate element only in certain regions between the inner lining and the base crucible. By way of example, it is possible to configure the intermediate element in the form of a profiled, in particular corrugated, foil arranged as a spacer at least in certain regions between the inner lining and the base crucible. During the melting of the Al₂O₃ powder and the formation of the sapphire single crystal, in this case the intermediate element can ensure the spacing between the base crucible and the inner lining. During cooling after single crystal formation, the intermediate element can, for example, be destroyed, in particular for example by shattering on account of a high brittleness of the intermediate element. The intermediate element can preferably likewise be formed from W, Mo, Re or an alloy of these materials. The provision of an intermediate layer of this type makes it possible to reduce the stresses acting on the single crystal which has formed, since stresses caused by different thermal expansions (in particular of the single crystal which has formed and of the crucible) can be absorbed by the intermediate layer, and therefore lower-stress crystals can be achieved. This makes it possible to achieve an increased quality of the crystals which are formed.

In terms of simplified production, at least the outer side of the inner lining in particular can be provided with surface structuring. The surface structuring can be introduced, for example by embossing, into the material of the inner lining and/or of the base crucible. By way of example, the surface structuring can be formed in such a manner that the inner lining touches the base crucible only in certain regions. The surface structuring can in this case be configured in particular in such a manner that the inner lining is held spaced apart from the inner wall of the base crucible on account of the surface structuring in large regions. It is thereby possible to ensure a good separability of the single crystal (together with the inner lining) from the base crucible. The provision of the surface structuring makes it possible for the single crystal which has formed to be simply and efficiently separated together with the inner lining from the base crucible. Since the base crucible is provided with the inner lining, repeated use of the base crucible for growing sapphire single crystals is made possible, where merely the inner lining needs to be replaced for the production of a further single crystal. The inner lining can in this case be formed with a considerably smaller wall thickness than the base crucible, as a result of which a significant saving of material is made.

According to one configuration, the inner lining has a wall thickness of <1 mm, preferably of <0.5 mm and more preferably of between 0.05 mm and 0.5 mm. In this case, the inner lining can be produced efficiently by deformation from, for example, a corresponding foil. Furthermore, a thin-walled configuration of this type saves a large amount of material. At least the inner lining preferably has a degree of purity of >99%, preferably of >99.9%, and therefore contamination of the molten mass can be reliably avoided. The degree of purity relates to how high the maximum proportion of constituents other than the base material or the elements of the base alloy may be. According to a preferred configuration, the base crucible likewise has a corresponding degree of purity.

According to a preferred configuration, at least the inner lining is formed from pure Mo with a degree of purity of >99%, preferably of >99.9%. In this case, the inner lining can also be provided with a high degree of purity within a satisfactory budget.

According to one configuration, the material of the inner lining differs from the material of the base crucible. By way of example, the inner lining can be produced from pure Mo or an alloy with a high Mo proportion, and the base crucible can be produced from W or an alloy with a high W proportion. In this case, the base crucible has on the one hand a low thermal expansion and therefore in particular a small degree of shrinkage upon cooling after the formation of the single crystal, which has a beneficial effect on the removability of the single crystal, and on the other hand the inner lining can be provided at relatively low cost and the risk of bonding between the inner lining and the base crucible can be minimized. In addition to the materials described, however, other material combinations are also possible, which both allow for bonding of the inner lining and the base crucible to be reliably prevented and ensure good removability of the single crystal. In particular, different materials selected from Mo, W and Re, or different alloys of these elements, can be used for the inner lining and the base crucible.

The object is also achieved by a process for growing sapphire single crystals using such a crucible, in which a sapphire single crystal is formed by solidification from the molten mass proceeding from a bottom region of the crucible. In particular, the single crystal formation can in this case be effected proceeding from a seed crystal arranged in the bottom region of the crucible. A process of this type in particular makes it possible to remove a sapphire single crystal which has formed from the crucible without the base crucible being destroyed. Repeated use of a base crucible is thereby made possible in a cost-effective manner.

The object is also achieved by the use of such a crucible in a process for growing sapphire single crystals, in which a sapphire single crystal is formed by solidification from the molten mass proceeding from a bottom region of the crucible.

Further advantages and functionalities of the invention will become apparent on the basis of the following description of exemplary embodiments with reference to the accompanying figures, in which:

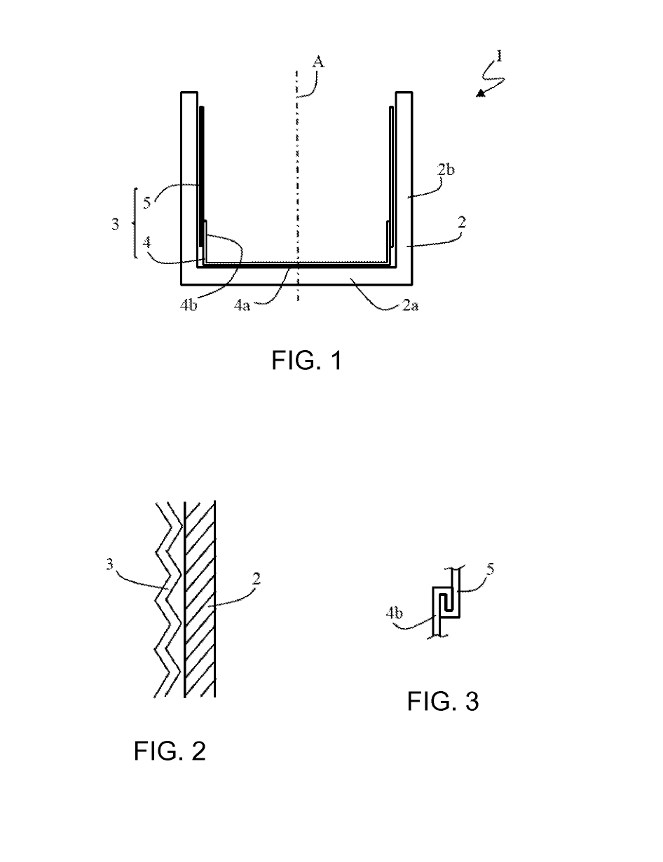

FIG. 1: shows a schematic illustration of a crucible for growing crystals according to one embodiment;

FIG. 2: shows a schematic illustration of a structure for facilitating the separability of the inner lining from the base crucible in the embodiment;

FIG. 3: shows a schematic illustration of a possible connection between a first portion and a second portion of an inner lining;

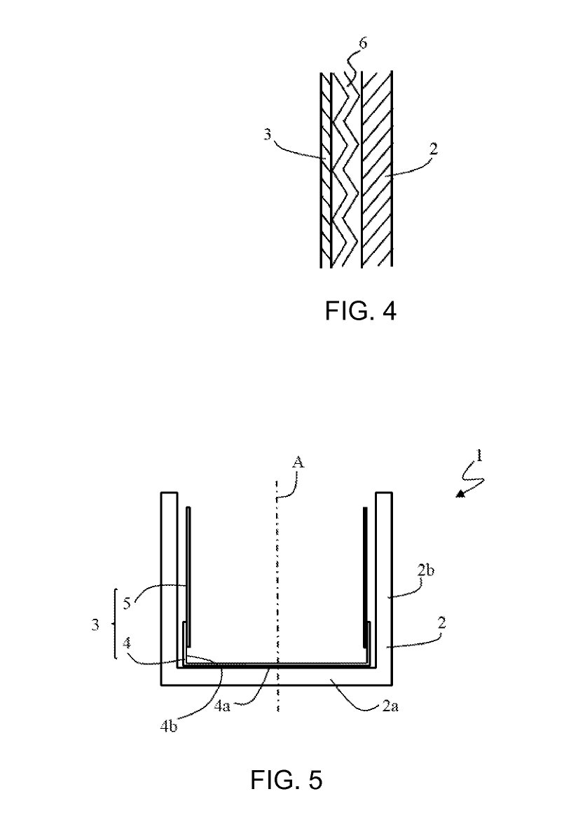

FIG. 4: shows a schematic illustration of a modification, in which a structure for facilitating the separability of the inner lining from the base crucible is formed by a separate intermediate element; and

FIG. 5: shows a schematic illustration of a crucible for growing crystals according to a modification of the embodiment.

An embodiment will be described hereinbelow with reference to FIG. 1 to FIG. 3.

FIG. 1 is a schematic illustration of a crucible -1- for growing crystals according to one embodiment. In the embodiment, the crucible -1- is designed specifically for growing sapphire single crystals.

The crucible -1- has a pot-like base crucible -2-, which can be produced from W (tungsten), Mo (molybdenum), Re (rhenium) or an alloy formed from at least two of these elements. The pot-like base crucible -2- is produced in one piece from the described material, with the material preferably having a purity of >99%, preferably of >99.9%. In one embodiment, the outer crucible is produced, for example, from high-purity W.

The base crucible -2- has a bottom region -2a- and a circumferential wall region -2b-. The base crucible -2- can be formed in particular in a substantially rotationally symmetrical manner about an axis -A-.

The base crucible -2- can be produced, for example, by powder metallurgy by way of pressing, sintering and if appropriate subsequent machining. In this case, by way of example, the crucible can have a wall thickness of between approximately 5 mm and 25 mm and preferably of between 10 mm and 20 mm in the wall region -2b-, and a wall thickness of up to 40 mm in the bottom region -2a-. However, it is also possible, for example, to produce the base crucible -2- from a metal sheet by deep drawing or pressing. In this case, the starting metal sheet can have, for example, a thickness of between 1 and 12 mm, preferably of between 2 and 6 mm. Although a base crucible -2- having a substantially uniform wall thickness is shown in FIG. 1, the wall thickness can vary both in the bottom region -2a- and in the wall region -2b-. The base crucible -2- can be produced from the desired material or the desired alloy in particular by powder metallurgy.

The crucible -1- also has an inner lining -3-, with which the base crucible -2- is lined on its inner side. The inner lining -3- can likewise be produced from W (tungsten), Mo (molybdenum), Re (rhenium) or an alloy formed from at least two of these elements. Here, the material of the inner lining preferably has a purity of >99%, preferably of >99.9%. In the embodiment, the inner lining -3- is produced, for example, from high-purity Mo.

The inner lining -3- has a pot-like first portion -4-, which covers the bottom region -2a- of the base crucible -2-, and a jacket-like second portion -5-, which at least partially covers the wall region -2b- of the base crucible -2-.

The pot-like first portion -4- is produced by forming from a foil and is substantially rotationally symmetrical about the axis -A-. The first portion -4- can be produced, for example, by deep drawing from a foil. The first portion -4- has a bottom -4a-, which covers the bottom region -2a- of the base crucible -2-, and a circumferential side wall -4b-, which extends in a bottom region of the wall region -2b- of the base crucible -2- substantially parallel to the wall region -2b-, such that a pot or tub shape closed at the bottom and at the sides is formed. The circumferential side wall -4b- in this case has a height in the range of between 10 mm and 25 mm, preferably of between 10 mm and 15 mm.

Both in the region of the base -4a- and in the region of the side wall -4b-, the pot-like first portion -4- has a wall thickness of between 0.05 mm and 1 mm, preferably of between 0.05 mm and 0.75 mm and more preferably of between 0.05 mm and 0.5 mm.

The second portion -5- of the inner lining -3- is likewise produced from a foil. The second portion -5- is formed as a separate component. The second portion -5- is produced from the same material as the first portion -4-. The second portion -5- is formed by coiling a planar foil into a substantially hollow cylindrical shape. The foil is coiled here in such a manner that the two end edges are arranged so as to overlap and are fixedly connected to one another, e.g. by a fold and/or by welding or sintering. However, it is also possible, for example, for the end edges to merely be tensioned against one another sealingly.

The first portion -4- and the second portion -5- are arranged in such a manner that the two portions overlap in a circumferential region. The region of overlap can in this case have a width of approximately 10 mm, for example. The first portion -4- and the second portion -5- are fixedly connected to one another in the overlapping region, e.g. by a fold and/or by welding or sintering. However, it is also possible, for example, for the second portion -5- to merely be tensioned against the first portion -4- sealingly (and not to be fixedly connected thereto), for example by a residual stress of the material of the second portion -5-. As an alternative or in addition, the first portion -4- and the second portion -5- can also be connected to one another by regions engaging into one another, as shown schematically in FIG. 3. In the illustration in FIG. 3, both the side wall -4b- of the first portion -4- and the second portion -5- are folded over in the overlapping region and hooked to one another, such that a particularly stable connection is achieved. Correspondingly, for example, the two above-described, interconnected end edges of the second portion -5- can also be connected to one another by regions engaging into one another.

In the exemplary embodiment shown in FIG. 1, the second portion -5- is arranged outside the first portion -4- in the overlapping region. However, it is also possible, for example, for the second portion -5- to be arranged inside the first portion -4- in the overlapping region, as shown schematically in the modification shown in FIG. 5.

In the embodiment, the inner lining -3- and the base crucible -2- are formed from different materials or different alloys. The materials or alloys are in this case selected in such a manner that, during the growth of sapphire single crystals in the crucible -1- (i.e. at the high temperatures required therefore), there is no bonding between the inner lining -3- and the base crucible -2-. If the inner lining -3- and the base crucible -2- are produced from different materials, the tendency toward bonding is lower than in the case in which they are formed from the same materials. Furthermore, the materials are selected in such a manner that both the base crucible -2- and the inner lining -3- have an adequate mechanical strength. With respect to the respective thermal expansion of the materials, the material combination is furthermore selected in such a manner that the single crystal which has formed can be removed from the base crucible -2- together with the inner lining -3-.

As will be explained hereinbelow with reference to the schematic illustration in FIG. 2, according to one development, provision can furthermore be made of a structure for facilitating the separability of the inner lining -3- from the base crucible -2- after formation of a sapphire single crystal. According to a first variant, at least an outer side of the inner lining -3- and/or at least an inner side of the base crucible -2- can be provided with surface structuring, which makes it possible to achieve simplified removability of the single crystal which has formed from the crucible -1-. As is shown schematically in FIG. 2, a surface structuring can be impressed into the material of the inner lining -3-, for example; this has the effect that the inner lining -3- does not bear against the material of the base crucible -2- over a large area, and instead leads to a certain spacing between the inner side of the inner lining -3- and the internal diameter of the base crucible -2-.

In addition to the production of the surface structuring by embossing, it is also possible for other methods to be used in order, in particular, to provide the inner lining -3- with surface structuring, which has the effect that the inner lining -3- does not bear areally against the material of the base crucible -2- over large regions. In addition to the preferred provision of the surface structuring on the inner lining -3-, it is also possible, for example, as an alternative or in addition thereto, to provide for this purpose surface structuring on the inner side of the base crucible -2-, in order to promote easy removability of the single crystal which has formed.

It is furthermore also possible to achieve a spacing between the inner lining -3- and the base crucible -2- in another way, for example by providing a multi-layer structure of the inner lining -3- or by the provision of corresponding spacers.

According to a modification shown schematically in FIG. 4, the structure for facilitating the separability of the inner lining -3- from the base crucible -2- is formed by a separate intermediate element -6- arranged at least in certain regions between the inner lining -3- and the base crucible -2-. In this respect, it is to be noted that the figures are merely schematic illustrations showing the wall thicknesses of the individual components not necessarily in the correct ratio. By way of example, the intermediate element -6- can be formed by a profiled foil provided as a spacer between the base crucible -2- and the inner lining -3-. The intermediate element -6- here is formed from W, Mo, Re or an alloy of these materials.

Even though merely a crucible -1- in which the inner lining -3- has the first portion -4- and the second portion -5- has been described with reference to the embodiment, it is also possible, for example, to provide a crucible -1- with a single-part inner lining -3-, in which a structure for facilitating the separability of the inner lining -3- from the base crucible -2- is provided in the form of surface structuring or in the form of a separate intermediate element -6-.

In a process for growing sapphire single crystals, a single-crystal sapphire seed crystal with a predefined crystallographic orientation is arranged in the bottom region of the crucible -1- inside the inner lining -3-, and the crucible -1- is filled up to a predefined fill level with Al₂O₃ starting material. Then, in a manner known per se, the Al₂O₃ starting material is converted into a liquid molten mass by a controlled temperature increase, and the seed crystal is countercooled in such a manner that, although it starts to melt on its surface, it is not completely melted. Targeted countercooling slowly deposits a sapphire single crystal from the molten mass proceeding from the seed crystal. After further cooling, the sapphire single crystal which has formed is removed together with the inner lining -3- from the base crucible -2-. The base crucible -2- is then provided with an inner lining -3- again and can be used once more for growing sapphire single crystals.

In addition to the process described, in which the seed crystal is arranged in the bottom region of the crucible -1-, it is also possible, for example, to use the crucible in a process in which the seed crystal is dipped from above into molten Al₂O₃, the sapphire single crystal is formed proceeding from this seed crystal and the sapphire single crystal which forms is slowly pulled upward partially or completely from the molten mass during the growth process.

1-15. (canceled)

16. A crucible for growing crystals including a sapphire single crystal, the crucible comprising:
a base crucible formed of W, Mo, Re or an alloy of W, Mo or Re, said base crucible having a substantially pot-shaped form, a bottom region and a wall region; and
an inner lining formed of W, Mo, Re or an alloy of W, Mo or Re, said inner lining having at least a pot-shaped first portion covering said bottom region of said base crucible and a jacket-shaped second portion at least partially covering said wall region of said base crucible;
said first portion and said second portion formed by separate components.

17. The crucible according to claim 16, wherein said pot-shaped first portion is formed from a reshaped foil.

18. The crucible according to claim 16, wherein said second portion is formed from a wound foil.

19. The crucible according to claim 16, wherein said first portion and said second portion are integrally connected to one another.

20. The crucible according to claim 16, wherein said first portion and said second portion have mutually engaging regions interconnecting said first portion and said second portion.

21. The crucible according to claim 16, which further comprises a structure configured to facilitate separability of said inner lining from said base crucible after formation of a sapphire single crystal.

22. The crucible according to claim 21, wherein said inner lining has at least an outer side with a surface, said base crucible has at least an inner side with a surface, and said structure is a structuring of at least one of said surfaces.

23. The crucible according to claim 21, which further comprises a separate intermediate element disposed between said inner lining and said base crucible and forming said structure.

24. The crucible according to claim 16, wherein said inner lining has a wall thickness selected from the group consisting of <1 mm, <0.5 mm and between 0.05 mm and 0.5 mm.

25. The crucible according to claim 16, wherein said inner lining has a degree of purity selected from the group consisting of >99% and >99.9%.

26. The crucible according to claim 16, wherein said inner lining is formed from pure Mo with a degree of purity of >99% or >99.9%.

27. The crucible according to claim 16, wherein said inner lining and said base crucible are formed of different materials.

28. A crucible for growing crystals including a sapphire single crystal, the crucible comprising:
a base crucible formed of W, Mo, Re or an alloy of W, Mo or Re, said base crucible having a substantially pot-shaped form and a wall thickness;
an inner lining formed of W, Mo, Re or an alloy of W, Mo or Re, said inner lining having a wall thickness smaller than said wall thickness of said base crucible; and
a structure configured to facilitate separability of said inner lining from said base crucible after formation of a sapphire single crystal.

29. The crucible according to claim 28, wherein said inner lining has at least an outer side with a surface, said base crucible has at least an inner side with a surface, and said structure is a structuring of at least one of said surfaces.

30. The crucible according to claim 28, which further comprises a separate intermediate element disposed between said inner lining and said base crucible and forming said structure.

31. The crucible according to claim 28, wherein said wall thickness of said inner lining is selected from the group consisting of <1 mm, <0.5 mm and between 0.05 mm and 0.5 mm.

32. The crucible according to claim 28, wherein said inner lining has a degree of purity selected from the group consisting of >99% and >99.9%.

33. The crucible according to claim 28, wherein said inner lining is formed from pure Mo with a degree of purity of >99% or >99.9%.

34. The crucible according to claim 28, wherein said inner lining and said base crucible are formed of different materials.

35. A process for growing sapphire single crystals using a crucible, the process comprising the following steps:
providing a crucible including a bottom crucible region, a base crucible formed of W, Mo, Re or an alloy of W, Mo or Re, the base crucible having a substantially pot-shaped form, a bottom region and a wall region, and an inner lining formed of W, Mo, Re or an alloy of W, Mo or Re, the inner lining having at least a pot-shaped first portion covering the bottom region of the base crucible and a jacket-shaped second portion at least partially covering the wall region of the base crucible, the first portion and the second portion formed by separate components; and
forming the sapphire single crystal by solidification from a molten mass proceeding from the bottom crucible region of the crucible.

36. A process for growing sapphire single crystals using a crucible, the process comprising the following steps:
providing a crucible including a bottom region, a base crucible formed of W, Mo, Re or an alloy of W, Mo or Re, the base crucible having a substantially pot-shaped form and a wall thickness, an inner lining formed of W, Mo, Re or an alloy of W, Mo or Re, the inner lining having a wall thickness smaller than the wall thickness of the base crucible, and a structure configured to facilitate separability of the inner lining from the base crucible after formation of a sapphire single crystal; and
forming the sapphire single crystal by solidification from a molten mass proceeding from the bottom region of the crucible.
